(19) United States
(12) Patent Application Publication
(10) Pub. No.: US 2003/0106487 A1
(43) Pub. Date: Jun. 12, 2003

(54) Photonic crystals and method for producing same

(76) Inventor: Wen-Chiang Huang, Auburn, AL (US)

Correspondence Address: Wen-Chiang Huang, 2076, S. Evergreen Dr., Auburn, AL, 36830, US

(21) Appl. No.: 10/006,382

(22) Filed: Dec. 10, 2001

(51) Int. Cl. C30B 7/00; C30B 21/02; C30B 28/06

(52) U.S. Cl. 117/68

(57) ABSTRACT

A photonic crystal material and a method for producing such a material according to a predetermined, two-dimensional or three-dimensional porous template. The method include the steps of: (A) preparing a porous template, wherein the preparation step includes the sub-steps of (i) dissolving a first material in a volatile solvent to form an evaporative solution, (ii) depositing a thin film of the solution onto a substrate, and (iii) exposing the solution film to a moisture environment while allowing the solvent in the solution to evaporate for forming the template that is constituted of an ordered array of micrometer- or nanometer-scaled air bubbles, which are surrounded with walls and are dispersed in a film of the first material; (B) filling the air bubbles with a second material; (C) at least partially removing the walls to create a plurality of voids; (D) refilling the voids with a third material; and (E) removing the second material from the air bubbles to obtain the photonic crystal material in the form of an array of air bubbles with walls made of the third material.

### BACKGROUND OF INVENTION

(1) Field of Invention

This invention relates to the fabrication of photonic crystal materials via templating by a 2-D or 3-D porous template that is characterized by a uniform distribution of meso- and macro-pores in the size range of 10 nm-20 μm surrounded by thin walls. In particular, the present invention relates to a method of producing such materials with which the formation of the meso-porous or macro-porous template structure is accomplished by a novel self-assembly mechanism involving thermo-capillary convection.

(2) Description of Prior Art

Porous solids have been utilized in a wide range of applications, including membranes, catalysts, energy storage, photonic crystals, microelectronic device substrate, absorbents, lightweight structural materials, and thermal, acoustical and electrical insulators. These solid materials are usually classified according to their predominant pore sizes: (i) micro-porous solids, with pore sizes <1.0 nm; (ii) macro-porous solids, with pore sizes exceeding 50 nm (normally up to 500 μm); and (iii) meso-porous solids, with pore sizes intermediate between 1.0 and 50 nm. The term “nano-porous solid” means a solid that contains essentially nanometer-scaled pores (1-1,000 nm) and, therefore, covers “meso-porous solids” and the lower-end of “macro-porous solids”.

One application in which a method for producing materials with a two-dimensional (2-D) or three-dimensional (3-D) pore pattern is useful is in photonic crystals. A review of the properties and applications of such materials can be found in an article by Joannopoulos, et al. entitled “Photonic Crystals: Putting a New Twist on Light,” Nature, Vol. 386, pp. 143-149 (Mar. 13, 1997). For simplicity, one may define a photonic crystal as a material with a periodic index of refraction, or a periodic array of small regions (e.g. pores) with a first dielectric constant, ε (e.g., ε≈1 for pores) dispersed in a matrix with a second dielectric constant. When the modulation of the refraction index or dielectric constant occurs on a length scale comparable to the wavelength of light (or an electromagnetic wave, EM), the material can modify the propagation of the photon or EM wave through the material via diffraction. The extreme example is a photonic crystal which possesses a complete photonic band gap, which is defined as a range of energies for which the photon or EM wave cannot propagate in any direction inside the material. This is analogous to the electronic band gap in a semiconductor material, which excludes the possibility that electrical charge carriers can have stationary energy states within the band gap. The major applications of photonic band gap materials are likely to be in the areas of the use and control of electromagnetic radiation in the wavelength range extending from the millimeter or microwave region to the ultraviolet region.

It has been very difficult to produce a photonic crystal because one must fabricate a structure which is patterned and highly ordered in two or three dimensions. In addition, one must be able to pattern materials having a high index of refraction, such as semiconductors. Severe difficulties have been encountered in applying traditional semiconductor processing techniques (e.g. electron beam lithography) to define such patterns. Specifically, the methods that may be employed to fabricate photonic band gap materials typically involve the mechanical drilling or machining of holes or cavities of macroscopic dimensions (of the order of millimeters or tenths of millimeters) in solid blocks of a dielectric material. The methods may also involve the concept of using physically directed and orientationally controlled chemical removal such as reactive ion etching to fabricate holes or cavities having dimensions of the order of microns in solid blocks of a dielectric material. These procedures suffer from the disadvantages that they are time consuming, expensive to perform, and require sophisticated and expensive machinery for their practice.

A promising approach to the fabrication of a photonic crystal or photonic band-gap material involves the preparation of a macro-porous or meso-porous template. A number of methods have previously been used to fabricate macro- or meso-porous inorganic films, although not necessarily intended for the production of photonic crystals. Meso-porous solids can be obtained by using surfactant arrays or emulsion droplets as templates. Latex spheres or block copolymers can be used to create silica structures with pore sizes ranging from 5 nm to 1 μm. Nano-porous silica films also can be prepared using a mixture of a solvent and a silica precursor, which is deposited on a substrate. When forming such nano-porous films by spin-coating, the film coating is typically catalyzed with an acid or base catalyst and additional water to cause polymerization or gelation and to yield sufficient strength so that the film does not shrink significantly during drying.

Another method for providing nano-porous silica films was based on the concept that film thickness and density (porosity, or dielectric constant) can be independently controlled by using a mixture of two solvents with dramatically different volatility. The more volatile solvent evaporates during and immediately after precursor deposition. The silica precursor, e.g., partially hydrolyzed and condensed oligomers of tetraethoxysilane (TEOS), is applied to a suitable substrate and polymerized by chemical and/or thermal methods until it forms a gel. The second solvent, called the Pore Control Solvent (PCS) is usually then removed by increasing the temperature until the film is dry. The density, porosity, or dielectric constant of the final film is governed by the volume ratio of low volatility solvent to silica. It has been found difficult to provide a nano-porous silica film having sufficiently optimized mechanical and dielectric properties, together with a relatively even distribution of material density throughout the thickness of the film.

Still another method for producing nano-porous inorganic materials is by following the sol-gel techniques, whereby a sol, which is a colloidal suspension of solid particles in a liquid, transforms into a gel due to growth and interconnection of the solid particles. Continued reactions within the sol will lead to a critical chemical state in which one or more molecules within the sol eventually reach macroscopic dimensions so that they form a solid network which extends substantially throughout the sol. At this chemical state, called the gel point, the material begins to become a gel. Hence, a gel may be defined as a substance that contains a continuous solid skeleton enclosing a continuous liquid phase. As the skeleton is porous, the term “gel” as used herein means an open-pored solid structure enclosing a pore fluid. Removal of the pore fluid leaves behind empty pores.

A useful nano-porous structure for photonic crystal applications must meet a number of criteria, including having a dielectric constant (ε) in selected periodic regions falling within the required value range, having a suitable thickness (t), and having an adequate mechanical strength. If the film is not strong enough, the pore structure may collapse, resulting in high material density and therefore an undesirably high dielectric constant.

Despite the availability of previous methods for preparing nano-porous silica films, an urgent need exists for further improvements in both nano-porous inorganic materials (including silica films) and methods for preparing the same. In particular, there remains a need for new methods which eliminate some or all of the aforementioned problems, such as providing methods for making silica nano-porous films of sufficient mechanical strength that are also optimized to have a desirable 2-D or 3-D array of low dielectric constant zones dispersed in higher dielectric constant matrix.

Milstein et al. (U.S. Pat. Nos. 5,385,114, 5,651,818 and 5,688,318) have described general methods for preparing photonic band gap materials in which the pores of a reticulated template are filled with a high index material. The high index material is incorporated into the template either as a liquid or gas and then solidified. The template may then be removed by chemical methods. Imhof et al. have described a method in which the template is filled by a gel. See Imhof et al., “Ordered Macroporous Materials by Emulsion Templating,” Nature, Vol. 389, pp. 948-951 (Oct. 30, 1997). Norris, et al. (U.S. Pat. No. 6,139,626) propose a method of producing a quantum-dot solid that also involves the utilization of a reticulated template. The method entails filling the pores in a template with colloidal nanocrystals. The quantum-dot solid is formed when the colloidal nanocrystals are concentrated as close-packed nanocrystals within the pores.

In the present invention, insofar as it pertains to photonic band gap materials, is an improvement over the prior art in that it allows nanometer-scale and/or micrometer-scale particles to fill the voids in a template, which is constituted of an ordered 2-D or 3-D array of air bubbles in a polymer film. The needed 2-D or 3-D templates can be mass-produced at a very high rate. Unlike the Milstein's liquid-filling method, the present invention does not have to require the extreme temperatures typically needed for melting high index materials. Further, unlike the gas-filling method of Milstein et al., the present invention does not require a deposition chamber, which is expensive and limits the total sample thickness attainable. The present invention is simpler, does not require a complicated apparatus, and is more flexible, both in terms of selecting the fill-material and the template. Unlike the method of Imhof et al., the present invention is not limited to metal oxides (such as alumina, silica, titania, zirconia, etc.) as the fill-material. Unlike Norris's method, the presently invented method is not limited to the formation of a patterned structure via filling of pores with colloidal nanocrystals. Any material which can be solution-synthesized can be utilized as the fill-material in the present invention. Further, unlike Norris's method, the present method is applicable to the fabrication of not just 3-D, but also 2-D photonic crystals.

The following open literature and patent documents are believed to represent the state of the art of the fabrication of nano-porous structures and photonic crystals (including photonic band gap materials):

1. M. Srinivasarao, et al., “Three-dimensionally ordered array of air bubbles in a polymer film,” Science, 292 (Apr. 6, 2001) pp.79-83.

2. O. Pitois and B. François, “Formation of ordered micro-porous membranes,” Eur. Phys. J., B8 (1999) 225-231; and “Crystallization of condensation droplets on a liquid surface,” Colloid Polymer Sci., 277 (1999) 574-578.

3. G. Widawski, G. Rawisco, and B. François, “Self-organized honeycomb morphology of star-polymer polystyrene films,” Nature, 369 (1994) 387-389.

4. H. W. Yan, et al., “A chemical synthesis of periodic macroporous NiO and metallic Ni,” Advanced Materials, 11 (1999) 1003-1006.

5. A. Blanco, et al. “Large-scale synthesis of a silicon photonic crystal with a complete 3-D bandgap near 1.5 micrometers,” Nature, 405 (2000) 437.

6. A. Imhof and D. J. Pine, “Ordered macroporous materials by emulsion templating,” Nature, 389 (Oct. 30, 1997) 948-951.

7. J. D. Joannopoulos, et al., “Photonic crystals: putting a new twist on light,” Nature, 386 (Mar. 13, 1997) 143-149.

8. J. Wijnhoven and W. L. Vos, “Preparation of photonic crystals made of air spheres in titania,” Science, 281 (Aug. 7, 1998) 802-804.

9. D. Velev, et al. “Porous silica via colloidal crystallization,” Nature, 389 (October 1997) 447-448.

10. K. M. Kulinowsky, et al. “Porous metals from colloidal templates,” Advanced Materials,” 12(2000)833.

11. J. B. Milstein and R. G. Roy, “Photonic band gap materials and method of preparation thereof,” U.S. Pat. Nos. 5,688,318 (Nov. 18, 1997); 5,651,818 (Jul. 29, 1997); 5,385,114 (Jan. 31, 1995).

12. D. J. Norris and Y. A. Vlasov, “Three-dimensionally patterned materials and methods for manufacturing same using nanocrystals,” U.S. Pat. No. 6,139,626 (Oct. 31, 2000).

13. P. R. Coronado, et al., “Method for rapidly producing micro-porous and meso-porous materials,” U.S. Pat. No. 5,686,031 (Nov. 11, 1997).

14. S. C. Jha, et al., “Composite porous media,” U.S. Pat. No. 6,080,219 (Jun. 27, 2000).

15. M. Moskovits, et al. “Nanoelectric devices,” U.S. Pat. No. 5,581,091 (Dec. 3, 1996).

16. R. L. Bedard, et al., “Semiconductor device containing a semiconducting crystalline nanoporous material,” U.S. Pat. No. 5,594,263 (Jan. 14, 1997).

17. D. L. Gin, et al., “Highly ordered nanocomposites via a monomer self-assembly in situ condensation approach,” U.S. Pat. No. 5,849,215 (Dec. 15, 1998).

18. M. G. Perrott, et al. “Liposome-assisted synthesis of polymeric nanoparticles,” U.S. Pat. No., 6,217,901 (Apr. 17, 2001).

19. H. F. A. Topsøe, et al., “Method for preparation of small zeotype crystals,” U.S. Pat. No. 6,241,960 (Jun. 5, 2001).

20. L. L. Murrell, et al. “Method for making molecular sieves and novel molecular sieve compositions,” U.S. Pat. No. 6,004,527 (Dec. 21, 1999).

21. T. J. Pinnavaia, et al. “Porous inorganic oxide materials prepared by non-ionic surfactant templating route,” U.S. Pat. No. 5,622,684 (Apr. 22, 1997).

22. C. J. Brinker, et al., “Method for making surfactant-templated, high-porosity thin films,” U.S. Pat. No. 6,270,846 (Aug. 7, 2001).

23. P. J. Bruinsma, et al., “Mesoporous-silica films, fibers, and powders by evaporation,” U.S. Pat. No. 5,922,299 (Jul. 13, 1999).

24. R. Leung, et al., “Nanoporous material fabricated using a dissolvable reagent,” U.S. Pat. No. 6,214,746 (Apr. 10, 2001).

25. R. Leung, et al., “Low dielectric constant porous films,” U.S. Pat. No. 6,204,202 (Mar. 20, 2001).

26. M. L. Oneill, et al., “Nanoporous polymer films for extreme low and interlayer dielectrics,” U.S. Pat. No. 6,187,248 (Feb. 13, 2001).

27. K. Lau, et al., “Nanoporous material fabricated using polymeric template strands,” U.S. Pat. No. 6,156,812 (Dec. 5, 2000).

28. S. K. Gordeev, et al., “Method of producing a composite, more precisely nanoporous body and a nanoporous body produced thereby,” U.S. Pat. No. 6,083,614 (Jul. 4, 2000).

29. H. O. Everitt, “Applications of Photonic Band Gap Structures,” Optics and Photonics News, vol. 3, No.11 (1992) 20-23.

### SUMMARY OF THE INVENTION

One embodiment of the present invention is a method for producing a photonic crystal material according to a predetermined, two-dimensional or three-dimensional porous template. This method includes five steps. The first step, Step (A), entails preparing a nano-porous template, wherein the preparation step includes three sub-steps: (i) dissolving a first material (e.g., a polymer, oligomer, or non-polymeric organic substance) in a volatile solvent to form an evaporative solution, (ii) depositing a thin film of this solution onto a substrate, and (iii) directing a moisture-containing gas to flow over the spread-up solution film while allowing the solvent in the solution to evaporate for forming a template, which is constituted of an ordered array of micrometer- or nanometer-scaled air bubbles surrounded with walls dispersed in a film of the first material.

Step (A) is then followed by the following four steps: (B) filling the air bubbles with a second material; (C) removing the walls to create a plurality of voids; (D) refilling the voids with a third material; and (E) removing the second material from the air bubbles to obtain the photonic crystal material in the form of an array of air bubbles with walls made of the third material.

A second preferred embodiment of the present invention is an alternative method for producing a photonic crystal material according to a predetermined, two-dimensional or three-dimensional porous template. This is a four-step method. The first step is identical to Step(A), described above, which is followed by the following three steps: (B′) filling the air bubbles with a second material to form an order array of particles; (C′) removing the walls to create a plurality of voids; and (D′) refilling the voids with a third material to obtain the photonic crystal material in the form of an array of particles made of the second materials surrounded with walls made of the third material, wherein the third material and the second material have different dielectric constants or indices of refraction. The resulting photonic crystal material is composed of an ordered array of low dielectric constant domains (second material) dispersed in a higher dielectric constant matrix (third material). This is in contrast to the photonic crystal material produced by the first version of the method, which is an array of air bubbles (dielectric constant ≈1) dispersed in a solid matrix material.

A third preferred embodiment of the present invention is another alternative method of producing a photonic crystal material according to a predetermined, two-dimensional or three-dimensional porous template. This is a three-step method. The first step is identical to Step(A), described above, which is followed by the following two steps: (B″) operating a material treatment means to the porous template in such a fashion that the walls become nano-porous and are functionally selective; and (C″) filling the nano-porous walls with a second material to obtain the photonic crystal material in the form of an array of air bubbles with walls made of a hybrid or composite material containing both the second material and the first material. In this embodiment, step (B″) preferably includes the sub-steps of partially removing the walls through a chemical, thermal, or mechanical means to produce nano-porous walls and chemically treating the nano-porous walls to impart a desired functional group to the walls. This functional group promotes wetting, impregnation, or infiltration of the walls by the second material during step (C″) in such a fashion that little or no second material will reside in the air bubbles at the conclusion of step (C″). The incorporation of the second material in the walls serves to impart desirable properties to the photonic crystal material, e.g., enhanced wall strength, modified dielectric constant of the walls and, hence, modified photon controlling characteristics.

Other preferred embodiments of the present invention include the photonic crystal materials and products made by the above three versions of the invented method.

Advantages of the Present Invention:

1. The templates can be mass-produced using a simple procedure and no expensive or complicated equipment is required. The over-all procedure is simple and easy to accomplish and, hence, is cost-effective. The formation of templates by using the current approach is faster and simpler than other template preparation techniques such as emulsion templating and co-polymer templating.

2. Both 2-D and 3-D templates, with air bubble sizes ranging from nanometer to millimeter scales, can be readily made and, therefore, both 2-D and 3-D photonic crystals can be fabricated using the presently invented method.

3. A wide variety of materials can be used to fill in the air bubbles and an even wider scope of compositions can be used as the bubble wall materials. Hence, an extremely wide range of photonic crystals can be readily fabricated to meet a great array of applications.

4. With the air bubbles filled with a liquid crystal, whose index of refraction and molecule orientation being tunable, the light flow pattern in the resulting photonic crystal is tunable by varying the temperature or imposing voltage.

### BRIEF DESCRIPTION OF THE DRAWINGS

FIG. 1A flowchart showing the essential steps of a method for producing photonic crystal materials in accordance with three preferred embodiments of the present invention.

FIG. 2A micrograph showing an example of a polystyrene-based template that contains pores surrounded by walls.

### DETAILED DESCRIPTION OF PREFERRED EMBODIMENTS

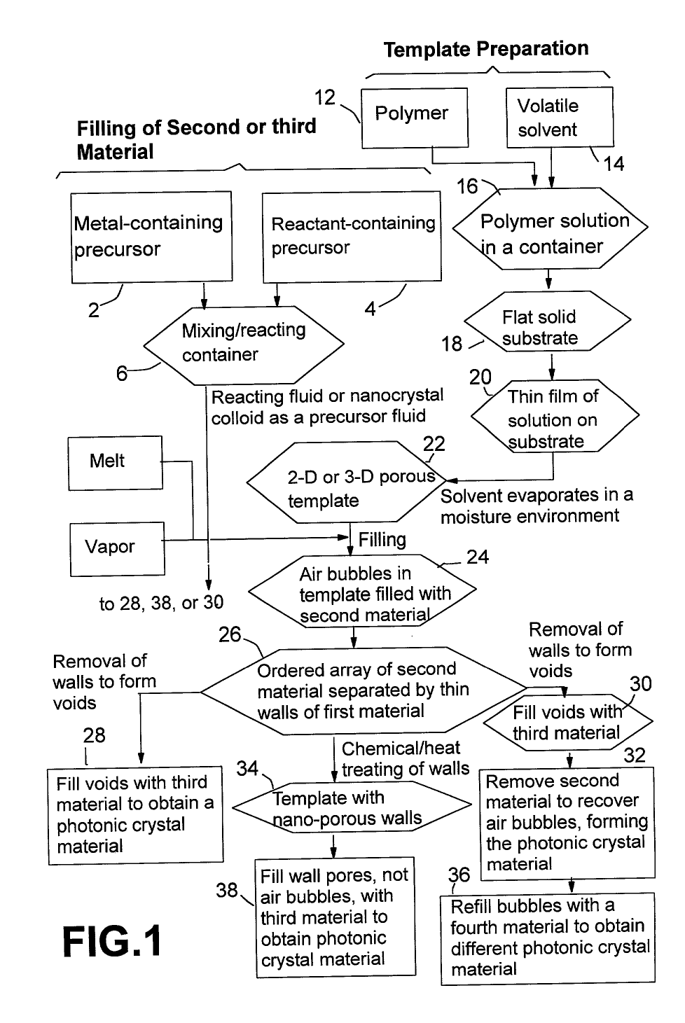

A preferred embodiment of the present invention is a method for producing a photonic crystal material according to a predetermined, two-dimensional or three-dimensional nano-, meso-, or macro-porous template made of a first material. The first step, Step (A), of this method involves the preparation of a porous template from the first material (preferably a polymer, but can be an oligomer or non-polymeric organic substance). Step (A) includes several sub-steps (FIG. 1):

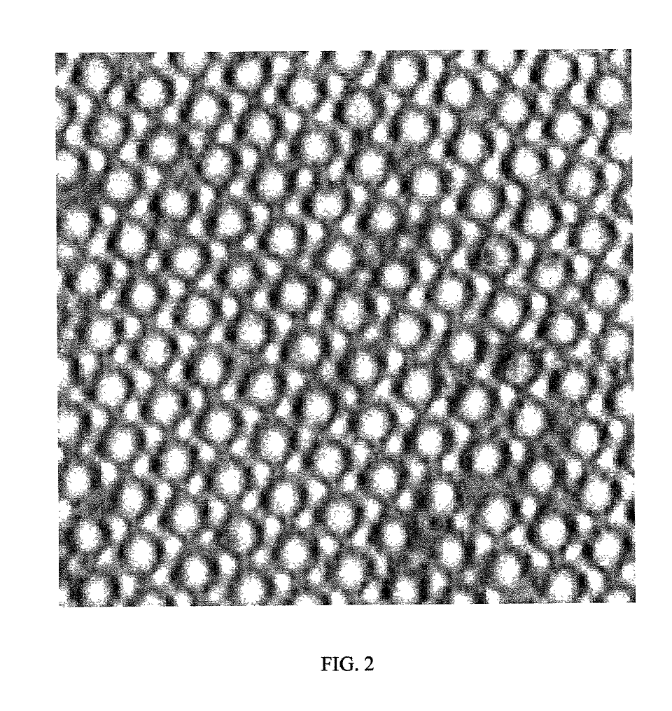

(i) dissolving the first material (e.g., a polymer 12) in a volatile solvent 14 to form an evaporative solution 16; (ii) depositing a thin film of this solution onto a substrate 18 (e.g., the surface of a boro-silicate glass or silicon wafer), and (iii) exposing the solution film 20 on the substrate to a moisture environment (e.g., by directing a moisture-containing gas to flow over this solution film) while, concurrently and/or subsequently, allowing the solvent in this solution to rapidly evaporate for forming a template 22. It is believed that rapid vaporization of the solvent induces a temperature reduction in the vicinity of the solution film. This low temperature environment is conducive to the formation of water droplets or “dew” near the solution-vapor interface. These water droplets, micrometer- or nanometer-scaled try to sink though the film made of the first material (e.g., a polymer). This first material or polymer makes up the walls of the water droplet. Water molecules eventually leave the film, leaving behind “air bubbles” or voids in the film template. Hence, the template is constituted of an ordered array of micrometer- or nanometer-scaled “air bubbles” with polymeric walls dispersed in a polymer film (e.g., FIG. 2) if the first material contains a polymer.

The preparation of a nano-porous polymer template is similar to the procedures used by M. Srinivasarao, et al. (Science, vol.292, Apr. 6, 2001, pp.79-83), G. Widawski, et al. (Nature, vol.369, Jun. 2, 1994, pp.387-389), and O. Pitois and B. François (Eur. Physical Journal, B8, 1999, pp.225-231). The polymers that can be used in practicing the present patent includes simple coil type polymers (e.g., linear polystyrene), star-shaped polymers (e.g., star-polystyrene), and rod-coil copolymers (e.g., polyparaphenylene-polystyrene block copolymer). A wide range of solvents can be used to dissolve these polymers, including benzene, toluene, and carbon disulfide (CS₂). We have found that low molecular weight polymers (oligomers) and some non-polymeric organic substances may also be used to create a template.

A thin layer of the prepared solution is deposited onto a flat substrate, e.g., via coating of the substrate by spin-coating, spray-coating, or dip-coating. The solvent in this thin layer of solution is allowed to rapidly evaporate in the presence of moisture. Since a large quantity of solution can be sprayed over to cover a large surface area of a substrate, this process can be used as a mass-production method. The procedure may be accelerated by sending a flow of moisture-containing nitrogen gas across the surface of this thin solution layer. In a matter of seconds, the solvent evaporates, leaving behind an ordered array of holes or air bubbles on the solid polymer film surface. These typically spherical holes are organized in a compact hexagonal network with micro-porous polymeric walls separating these spherical holes. We have found that, by manipulating the temperature, moisture level, and gas flow rate, one can vary the pore sizes in a controlled fashion. Although M. Srinivasarao, G. Widawski, O. Pitois, and their respective co-workers have observed that the pore sizes are within the range of 0.20 to 20 μm, we have found that uniformly-sized nano pores with a pore size in the range of 10-1,000 nm are also readily obtainable.

Depending on the relative density of the solvent used with respect to the density of water, the resulting template can be a two-dimensional template comprising one layer of air bubbles dispersed in the first material, or a three-dimensional template comprising multiple layers of air bubbles dispersed in the first material. When a solvent less dense than water is used, such as benzene or toluene, a multi-layer structure or 3-D template results, each layer being composed of a normally hexagonal array of air bubbles. When a solvent denser than water is used, such as carbon disulfide, a single-layer of pores or 2-D template is obtained.

Step (A) is then followed by the following four steps: (B) filling the air bubbles 24 with a second material to form a structure 26 being composed of an ordered array of second-material domains dispersed in the first-material matrix; (C) removing the walls to create a plurality of voids; (D) refilling the voids with a third material 30; and (E) removing the second material from the air bubbles to obtain the photonic crystal material 32 in the form of an array of air bubbles with walls made of the third material. The second material is selected in such a fashion that, after filling up the air bubbles, it serves as a tentative supporting template material when and after the walls are removed to create a network of voids. These voids are filled with a desired new wall material (the third material), which is to stay as the matrix material in the final photonic crystal material. The second material is then removed to recover the air bubbles, which have a minimal dielectric constant (ε≈1).

The primary reason for replacing the first material with the third material is to extend the applicability range of the presently invented method. The original wall material is normally a polymer, oligomer (low molecular weight version of a polymer), or a non-polymeric organic substance which does not necessarily have the desired dielectric constant or index of refraction for a specific application. This first material may be replaced by a third material with a desired physical constants via filling the voids that were created by removing the first material. A much wide range of materials may be used to fill these voids, including other organic, other polymeric, metallic, ceramic, glass, and carbonaceous materials.

The second material may be selected from the group consisting of (a) a material with a melting point (Tm) higher than the melting point of the first material, (b) a material with a solubility (Su) in a solvent lower than the solubility of the first material in the same solvent, or (c) a material with higher thermal stability (Ts) than the first material. The selection of a higher-Tm second material is to make it possible to selectively fuse the first material to become a fluent melt, which is allowed to be readily removed to create voids. With a much higher solubility in a solvent, the first material can be readily dissolved in this solvent (to create voids) without significantly dissolving the second material. With a much poorer thermal stability, the first material can be readily thermally degraded and removed without removing the second material when the composite material (containing both first and second material) is exposed to a high temperature. A wide variety of materials with a different Tm, Su, and/or Ts can be used for the present purpose.

The third material may be selected from the group consisting of a ceramic, glass, metal, carbon, polymer, or a combination thereof. A particularly suitable material is silica, for instance. Other suitable third materials include any material selected from the group consisting of: (a) polycrystalline aluminum oxide and single crystalline aluminum oxide; (b) other oxides including chromium-doped aluminum oxide, titanium-doped aluminum oxide, yttrium aluminum garnet, other synthetic garnets, perovskites, spinels, and the like; (c) elemental materials such as silicon, germanium and the like; (d) compounds formed from elements in columns III and V of the periodic table such as gallium arsenide, indium phosphide, and similar compounds or ternary or higher order alloys of these compounds, such as gallium aluminum arsenide; (e) compounds formed from elements in columns II and VI of the periodic table such as zinc selenide, zinc sulphide, cadmium telluride, mercury telluride and similar compounds or ternary or higher order alloys of these compounds, such as mercury cadmium telluride; (f) rare-earth doped oxide glass; and (g) materials having high dielectric constant which can be infiltrated into a porous body and then solidified, such as epoxies and plastics.

The above-cited materials can be used to impregnate the voids (if in a liquid or melt state) or to infiltrate the voids (if in a vapor state). Impregnation or infiltration methods are well-known in the art. Several other ways can be followed to fill the voids with the third material. For instance, one may choose to fill the voids with a sufficient amount of colloidal nanocrystals. Specifically, step (D) may include the sub-steps of: (D-i) dispersing colloidal nanocrystals in a solvent which is unreactive with respect to the second material to provide a colloidal nanocrystal solution and then (D-ii) filling the voids created in step (C) with the colloidal nanocrystal solution. The proportions of the colloidal nanocrystals and the solvent are selected so that there is a sufficient quantity of nanocrystals to completely fill the voids. Step (D) may further include a sub-step of adding a surface capping agent to the solvent in which the nanocrystals are dispersed, whereby the colloidal nanocrystals are stabilized by the surface capping agent in the solvent, and the colloidal nanocrystals are prevented from agglomerating.

A solution impregnation approach can be followed to fill the air bubbles with the second material or to impregnate the voids (created by the walls removed) with the third material. Referring to FIG. 1 again, the solution can be prepared from, say, a metal-containing precursor 2 and a reactant-containing precursor 4, which are mixed together in a container 6 to form a reacting fluid. This reacting fluid may then be introduced into the air bubbles (for filling of second material) or the voids (for filling of third material). The following examples serve to illustrate how the voids can be impregnated with a third material through a solution impregnation or colloidal solution impregnation approach:

### EXAMPLE 1

In order to prepare cadmium telluride material, a nearly stoichiometric ratio of Cd(CH₃)₂ (dimethylcadmium) in (n-C₈H₁₇)₃ P (tri-n-octylphosphine or “TOP”) and (n-C₈H₁₇)₃ PTe (tri-n-octylphosphinetelluride or “TOPTe”) in TOP were mixed together in a controlled-atmosphere glove box to form a reacting solution. The solution was introduced into the voids, which were previously occupied by pore walls in a polystyrene template. The interstitial solution in the pores underwent precipitation of CdTe nuclei in a liquid TOP solution. The liquid TOP solvent was then evaporated, leaving behind nano particles in the cavities. This process was repeated three times until essentially all of the voids were filled with CdTe crystals.

### EXAMPLE 2

The TOP-based reacting solution prepared in EXAMPLE 1 was mixed with liquified (n-C₈H₁₇)₃ PO (tri-n-octylphosphine oxide or “TOPO”) solvent maintained at the desired reaction temperature from 54° C. to about 125° C. under N₂. The solution mixture was introduced into the voids in the template to generate TOPO-capped CdTe particles. After a nominal reaction period of from about one minute to about 60 minutes, in inverse relationship to the reaction temperature, TOPO-capped cadmium telluride particles were precipitated. The resulting film with a 2-D ordered array of air bubbles surrounded with CdTe crystals was washed with methanol and dried to obtain a photonic crystal material.

### EXAMPLE 3

CdS particles were prepared by reacting CdI₂ in methanol with Na₂S in methanol at reduced temperature under inert atmosphere as follows:

CdI₂+Na₂S (in MeOH) [symbol] CdS (particles)+2 NaI(soluble in MeOH)

The by-product of the reaction (i.e., NaI) is soluble in the methanol solvent while the product nano particles of CdS are not. During the chemical reaction, NaI salt is removed from the product mixture with the remaining CdS nano particles forming a stable methanolic colloid. The methanol colloid was poured into the voids created by removing the original pore walls from a porous polystyrene template on a glass surface. Methanol is then allowed to vaporize, leaving behind the CdS material trapped inside the voids.

### EXAMPLE 4

Samples of photonic crystals containing III-V compound semiconductor nano crystals were prepared through the following route: First, (NaK)₃E (E=P, As) was synthesized in situ under an argon atmosphere by combining sodium/potassium alloy with excess arsenic powder or excess white phosphorus in refluxing toluene. To this was added a GaX₃ (when E=As, X=Cl, I; when E=P, X=Cl) solution in diglyme. For the case of GaAs, the mixture was refluxed for 24 hours. The mixture solution was poured over the surface of a template containing voids that were earlier occupied by the walls. The solvent was then removed. The resulting composite film was washed with deionized water, which was used to destroy any unreacted arsenide and to dissolve the alkali metal halide products. In the case of the GaP reactions, an ethanol/deionized water solution was used for the same purpose due to solubility of unreacted white phosphorus in ethanol. The resulting film was then vacuum treated and the solid film collected. The dry solid was heated to 350° C. in a sublimator under dynamic vacuum for 2-3 hrs to remove excess Group V element. The resulting light to dark brown materials trapped inside the voids were GaAs and GaP crystals.

The method may further include an additional step, i.e., after step (E), a step (F) may be taken to refill the air bubbles with a fourth material that has a different dielectric constant or refraction index than the third material to obtain a different photonic crystal material 36. Preferably, this fourth material has a much lower dielectric constant or index of refraction than the third material. Another preferred fourth material is a liquid crystal material. It is known in the art that impregnation of the periodic pores with a liquid crystal makes a photonic crystal become tunable since the refraction index of a liquid crystal varies with temperature and the light flow direction varies with the imposing voltage that changes the molecular chain orientation.

It may be noted that the solution impregnation approach does not have to involve a reacting solution. A non-reactive solution can lead to precipitation of the desired second material in the air bubbles or third material in the voids created by removal of walls upon evaporation of the constituent solvent. For instance, in the case of polycarbonate-solvent solution, the wall-induced voids could be filled with polycarbonate once the solvent is evaporated. This procedure does not involve any chemical reaction.

A second preferred embodiment of the present invention is an alternative method for producing a photonic crystal material according to a predetermined, two-dimensional or three-dimensional porous template. This is a four-step method. The first step is identical to Step(A), described above, which is followed by the following three steps:

(B′) filling the air bubbles with a second material to form an ordered array of particles (similar to Step (B) discussed above);

(C′) removing the walls to create a plurality of voids (similar to Step (C) discussed above); and

(D′) refilling the voids with a third material to obtain the photonic crystal material 28 in the form of an array of particles made of the second materials surrounded with walls made of the third material, wherein the third material and the second material have different dielectric constants or indices of refraction.

This Step (D′) is similar to Step (D) described above, but the second material is not removed from the air bubbles. As a consequence, the resulting photonic crystal material is composed of an ordered array of low dielectric constant domains (second material) dispersed in a higher dielectric constant matrix (third material). This is in contrast to the photonic crystal material produced by the first version of the method, which is an array of air bubbles (dielectric constant ε≈1) dispersed in a solid matrix material. The void-filling materials and processes are similar to those used in the first version of the method described above.

A third preferred embodiment of the present invention is another alternative method of producing a photonic crystal material according to a predetermined, two-dimensional or three-dimensional porous template. This is a three-step method. The first step is identical to Step(A), described above, which is followed by the following two steps:

(B″) operating a material treatment means to the porous template in such a fashion that the walls become nano-porous walls 34 and are functionally selective; and

(C″) filling the nano-porous walls with a second material to obtain the photonic crystal material 38 in the form of an array of air bubbles with walls made of a hybrid or composite material containing both the second material and the first material.

In this embodiment, step (B″) preferably includes a sub-step of partially removing the walls through a chemical, thermal, or mechanical means to produce nano-porous walls. This can be accomplished through selective etching by a chemical or partial dissolution by a solvent. A skeleton of the original walls is allowed to remain after selective etching or partial dissolution. These scaffolds or nano-porous walls are then chemically treated to impart a desired functional group to the walls. For instance, a polar functional group may be attached to the wall skeleton surface so that this group could preferentially attract the intended third material or a precursor to the intended third material. This functional group promotes wetting, impregnation, or infiltration of the walls by the second material during step (C″) in such a fashion that little or no second material will reside in the air bubbles at the conclusion of step (C″). The incorporation of the second material in the walls serves to impart desirable properties to the photonic crystal material. For instance, the wall strength can be enhanced and the dielectric constant of the walls can be increased or adjusted so that a different photonic crystal material is obtained. Optionally, the air bubbles, after step (C″) may be re-filled with a third material, which could be a liquid crystal material.

### EXAMPLE 5

A polystyrene-based template was placed in the upper portion of a sealed chamber, above the toluene liquid level contained in the chamber. Toluene was heated to 45° C. to allow a small portion of the toluene liquid to vaporize into the upper portion of the chamber. After approximately 30 minutes, the pore walls became nano-porous. The sample was then exposed to the vapor of (n-C₈H₁₇)₃ PO (tri-n-octylphosphine oxide or “TOPO”) solvent maintained at 54° C. for 10 minutes, permitting some TOPO molecules to be adsorbed onto the nano pores in the wall. The template was then immersed in the solution prepared in EXAMPLE 1, removed and dried. Nano-scaled CdTe particles were found to precipitate out and reside preferentially in the nano pores of the template walls. The sub-steps of immersion and drying could be repeated two or three times until the pores of the walls are completely filled with a desired material.

The resulting products prepared by the presently invented method as specified in the above three embodiments could include hybrid organic/inorganic films with controlled pore structure and surface chemistry. These materials are of interest for a range of applications including membranes, sensors, low dielectric constant (low ε) films, and optical hosts, in addition to photonic crystal materials. Films with controlled pore structure and high porosity (that is, greater than 50%) are particularly attractive to applications requiring materials with low dielectric constants (for example, dielectric constants less than 2). Due to the high level of porosity and low pore dielectric constant (ε≈1), the presently invented method readily provides a product that meets this requirement.

In the above three embodiments of the presently invented method, in order to produce a thicker 3-D photonic crystal, one may choose to prepare a thicker 3-D template by repeating sub-steps (A-ii) and (A-iii). Specifically, one can deposit a thin film of this solution onto a substrate, which is exposed to a moisture environment (e.g., by directing a moisture-containing gas to flow over this solution film) while allowing the solvent in this solution to rapidly evaporate for forming a first lamina of a template. This sub-step is followed by deposition of a second layer of solution film onto the first layer to form a second lamina of the template when the solvent in the second layer is vaporized. These sub-steps are repeated until a desired number of laminas are stacked together to form a thick, 3-D template. Since the second and subsequent layers are of identical chemical compositions to the same layer, there is excellent chemical compatibility between layer, resulting in the formation of an integral 3-D template. This thick, 3-D template is then subjected to the air bubble-filling, wall-removing, wall-treating, and/or void-filling steps to produce a photonic crystal material. Alternatively, during the above repetitive template preparation process, one may choose to intermittently fill the air bubbles with a second material and/or fill the voids (created by the removal of bubble walls) with a third material to a lamina or a selected number of laminas prior to deposition of a successive template lamina.

Another three embodiments of the present invention are the three photonic crystal materials respectively prepared by the above three versions of the invented methods. These materials can be used to control the propagation of an electromagnetic wave.

1. A method for producing a photonic crystal material according to a predetermined, two-dimensional or three-dimensional porous template, the method comprising the steps of:
(A) preparing said porous template, wherein said preparation step comprises the sub-steps of (i) dissolving a first material in a volatile solvent to form an evaporative solution, (ii) depositing a thin film of said solution onto a substrate, and (iii) exposing said solution film to a moisture environment while allowing the solvent of said solution to evaporate for forming said template which is constituted of an ordered array of micrometer- or nanometer-scaled air bubbles which are surrounded with walls and are dispersed in a film of said first material;
(B) filling said air bubbles with a second material;
(C) at least partially removing said walls to create a plurality of voids;
(D) refilling said voids with a third material; and
(E) removing said second material from said air bubbles to obtain the photonic crystal material in the form of an array of air bubbles with walls made of said third material.

2. A method for producing a photonic crystal material according to a predetermined, two-dimensional or three-dimensional porous template, the method comprising the steps of:
(A) preparing said porous template, wherein said preparation step comprises the sub-steps of (i) dissolving a first material in a volatile solvent to form an evaporative solution, (ii) depositing a thin film of said solution onto a substrate, and (iii) exposing said solution film to a moisture environment while allowing the solvent of said solution to evaporate for forming said template which is constituted of an ordered array of micrometer- or nanometer-scaled air bubbles which are surrounded with walls and are dispersed in a film of said first material;
(B) filling said air bubbles with a second material to form an order array of particles of said second material;
(C) removing said walls, at least partially, to create a plurality of voids; and
(D) refilling said voids with a third material to obtain the photonic crystal material in the form of an array of particles made of said second materials surrounded with walls made of said third material, wherein said third material and said second material have different dielectric constants or indices of refraction.

3. A method for producing a photonic crystal material according to a predetermined, two-dimensional or three-dimensional porous template, the method comprising the steps of:
(A) preparing said porous template, wherein said preparation step comprises the sub-steps of (i) dissolving a first material in a volatile solvent to form an evaporative solution, (ii) depositing a thin film of said solution onto a substrate, and (iii) exposing said solution film to a moisture environment while allowing the solvent of said solution to evaporate for forming said template which is constituted of an ordered array of micrometer- or nanometer-scaled air bubbles which are separated by walls and are dispersed in a film of said first material;
(B) operating a material treatment means to said porous template in such a fashion that said walls become nano-porous and are functionally selective; and
(C) filling said nano-porous walls with a second material to obtain the photonic crystal material in the form of an array of air bubbles with walls made of said second material and said first material.

4. The method of claim 1, 2, or 3 wherein sub-step (A-iii) is performed by directing a moisture-containing gas to flow over said solution film while allowing the solvent of said solution to evaporate for forming said porous template.

5. The method of claim 1, 2, or 3 wherein said first material is selected from the group consisting of a polymer, oligomer, and non-polymeric organic materials.

6. The method of claim 1 or 2 wherein said second material is selected from the group consisting of (a) a material with a melting point higher than the melting point of said first material, (b) a material with a solubility in a solvent lower than the solubility of said first material in the same solvent, or (c) a material with higher thermal stability than said first material.

7. The method of claim 1 or 2, wherein said third material is selected from the group consisting of a ceramic, glass, metal, carbon, polymer, or a combination thereof.

8. The method of claim 1 or 2 wherein said third material contains silica.

9. The method of claim 1, further comprising, after step (E), a step of refilling the air bubbles with a fourth material that has a different dielectric constant or refraction index than said third material.

10. The method of claim 1, 2, or 3 wherein said template is a two-dimensional template comprising one layer of air bubbles dispersed in said first material.

11. The method of claim 1, 2, or 3 wherein said template is a three-dimensional template comprising multiple layers of air bubbles dispersed in said first material.

12. The method of claim 1 or 2 wherein step (D) includes the sub-steps of (D-i) dispersing colloidal nanocrystals in a solvent which is unreactive with respect to said second material to provide a colloidal nanocrystal solution and (D-ii) filling the voids created in step (C) with said colloidal nanocrystal solution.

13. The method of claim 12, wherein the proportions of the colloidal nanocrystals and the solvent are selected so that there is a sufficient quantity of nanocrystals to completely fill said voids.

14. The method of claim 12, wherein step (D) further includes a sub-step of adding a surface capping agent to said solvent in which the nanocrystals are dispersed, whereby the colloidal nanocrystals are stabilized by the surface capping agent in the solvent, and the colloidal nanocrystals are prevented from agglomerating.

15. The method of claim 1 or 2, wherein said third material is selected from the group consisting of:
a). polycrystalline aluminum oxide and single crystalline aluminum oxide,
b). other oxides including chromium-doped aluminum oxide, titanium-doped aluminum oxide, yttrium aluminum garnet, other synthetic garnets, perovskites, spinels, and the like,
c). elemental materials such as silicon, germanium and the like,
d). compounds formed from elements in columns III and V of the periodic table such as gallium arsenide, indium phosphide, and similar compounds or ternary or higher order alloys of these compounds, such as gallium aluminum arsenide,
e). compounds formed from elements in columns II and VI of the periodic table such as zinc selenide, zinc sulphide, cadmium telluride, mercury telluride and similar compounds or ternary or higher order alloys of these compounds, such as mercury cadmium telluride,
f). rare-earth doped oxide glass, and
g). and materials having high dielectric constant which can be infiltrated into a porous body and then solidified, such as epoxies and plastics.

16. A photonic crystal material patterned according to a predetermined, two-dimensional or three-dimensional template, produced according to the method of claim 1, 2, or 3.

17. The method of claim 2, wherein the dielectric constant of said third material is higher than the dielectric constant of said second material.

18. The method of claim 3, wherein step (B) comprises the sub-steps of partially removing said walls through a chemical, thermal, or mechanical means to produce nano-porous walls and chemically treating said nano-porous walls to impart a desired functional group to said walls, wherein said functional group promotes wetting, impregnation, or infiltration of said walls by said second material during step (C).

19. The method of claim 3, wherein said second material is selected from the group consisting of a ceramic, glass, metal, carbon, polymer, or a combination thereof.

20. The method of claim 1, 2, or 3, wherein the sub-step (A-ii) of depositing a thin film of said solution onto a substrate comprises a sub-step of coating said substrate by spin-coating, spray-coating, or dip-coating.

21. The product of claim 1, 2, or 3, used as a material selected from the group consisting of a low-dielectric film, membrane and sensor material.

22. The method of claim 2, wherein said second material comprises a liquid crystal material.

23. The method of claim 9, wherein said fourth material comprises a liquid crystal material.

24. The method of claim 3, further comprising a step of re-filling said air bubbles, after step (C), with a third material.

25. The method of claim 24, wherein said third material comprises a liquid crystal material.

26. The method of claim 1, 2, or 3, wherein sub-steps (A-ii) and (A-iii) are repeated a predetermined number of times to form a multi-lamina template, wherein a thin film of solution is deposited onto a preceding film after the solvent in the preceding film has been partially or completely evaporated to form a lamina.

27. The method of claim 26, wherein the air bubbles in a lamina or a number of laminas are filled with a second material before a successive film solution is deposited.

28. The method of claim 26, wherein the bubble walls in a lamina or a number of laminas are at least partially removed before a successive film solution is deposited.
